(19) United States
(12) Patent Application Publication
(10) Pub. No.: US 2023/0307856 A1
(43) Pub. Date: Sep. 28, 2023

(54) LOW PROFILE IMPEDANCE-TUNABLE AND CROSS-TALK CONTROLLED HIGH SPEED HYBRID SOCKET INTERCONNECT

(71) Applicant: Intel Corporation, Santa Clara, CA (US)

(72) Inventors: Emad S. AL-MOMANI, Portland, OR (US); Ismael FRANCO NÚÑEZ, Milwaukie, OR (US)

(21) Appl. No.: 17/703,730

(22) Filed: Mar. 24, 2022

(51) Int. Cl. H01R 12/71; H05K 7/10; H01R 13/6461; H01R 13/6466; H01R 13/24; H01R 43/20

(52) U.S. Cl. CPC H01R 12/714; H05K 7/1023; H01R 13/6461; H01R 13/6466; H01R 13/2414; H01R 43/205

(57) ABSTRACT

Embodiments disclosed herein include sockets and socket architectures. In an embodiment, a socket comprises a substrate. In an embodiment, an opening is provided through the substrate. In an embodiment, an elastomeric pin inserted into the opening. In an embodiment, the elastomeric pin is electrically conductive.

### TECHNICAL FIELD

Embodiments of the present disclosure relate to electronic packages, printed circuit boards, and more particularly to socket architectures that include elastomeric pins that are shielded by vias or solid conductive plating surrounding the elastomeric pins.

### BACKGROUND

Sockets for original equipment manufacturer (OEM) high volume manufacturing (HVM) and validation are under ever growing demand for supporting faster data transfer rates and more stringent power delivery requirements. Existing OEM socket technology only supports the lower ranges of projected top double data rate (DDR) speeds. Additionally, silicon validation has required that certain system on chips (SOCs) be soldered down to validate interfaces running at full speed since the socket would degrade the interface to the point of failure. In the case of high core-count products, very demanding power delivery requirements are needed. Existing socket architectures may not be able to meet such demands. Furthermore, high performance, coaxial/shielded sockets are very expensive to manufacture.

### BRIEF DESCRIPTION OF THE DRAWINGS

FIG. 1A is a cross-sectional illustration of a socket with elastomeric pins that pass through a thickness of a socket substrate, in accordance with an embodiment.

FIG. 1B is a plan view illustration of a socket with elastomeric pins, in accordance with an embodiment.

FIG. 2A is a cross-sectional illustration of an electronic system with a socket between the package substrate and the board, in accordance with an embodiment.

FIG. 2B is a cross-sectional illustration of an electronic system with a socket with a land grid array (LGA) interface with the package substrate, in accordance with an embodiment.

FIG. 3A is a cross-sectional illustration of a portion of a socket a with pin on the top surface that is offset from an underlying pin on the bottom surface, in accordance with an embodiment.

FIG. 3B is a cross-sectional illustration of a portion of a socket with pins that are capacitively coupled to each other, in accordance with an embodiment.

FIG. 3C is a cross-sectional illustration of a portion of a socket with pins that are coupled together by a conductive via through a portion of the socket substrate, in accordance with an embodiment.

FIG. 4A is a cross-sectional illustration of a socket substrate, in accordance with an embodiment.

FIG. 4B is a cross-sectional illustration of the socket substrate after an opening is formed through the socket substrate, in accordance with an embodiment.

FIG. 4C is a cross-sectional illustration of the socket substrate after sidewalls of the opening are plated, in accordance with an embodiment.

FIG. 4D is a cross-sectional illustration of the socket substrate after a fill layer fills the opening, in accordance with an embodiment.

FIG. 4E is a cross-sectional illustration of the socket substrate after an opening is formed in the fill layer and an elastomeric pin is inserted into the opening, in accordance with an embodiment.

FIG. 5 is a plan view illustration of a socket with a plurality of signaling pins surrounded by ground and/or power pins, in accordance with an embodiment.

FIG. 6 is a schematic of a computing device built in accordance with an embodiment.

### EMBODIMENTS OF THE PRESENT DISCLOSURE

Described herein are socket architectures that include elastomeric pins that are shielded by vias surrounding the elastomeric pins, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, existing socketing architectures are not suitable for high performance systems, such as those described above. Accordingly, embodiments disclosed herein include socket architectures that utilize elastomeric pin structures. In some embodiments, the elastomeric pin structures are surrounded by vias in order to provide improved electrical isolation between the signaling pins. In certain embodiments, the electrical performance of the elastomer pins and the shielding virtually eliminates the impedance and cross-talk dependency on the pin pattern. The elastomeric properties also improve the mechanical robustness needed for many different applications.

In some embodiments, the socket architecture is suitable for use with ball grid array (BGA) interfaces with the package substrate. In other embodiments, the socket architecture is suitable for use with land grid array (LGA) interfaces with the package substrate. In yet another embodiment, the elastomeric pins are a single structure that passes through the socket substrate. In other embodiments, a top pin may be coupled to a bottom pin. For example, the coupling between the top pin and the bottom pin may be made through capacitive coupling, or through an electrical connection (e.g., vias, traces, etc.).

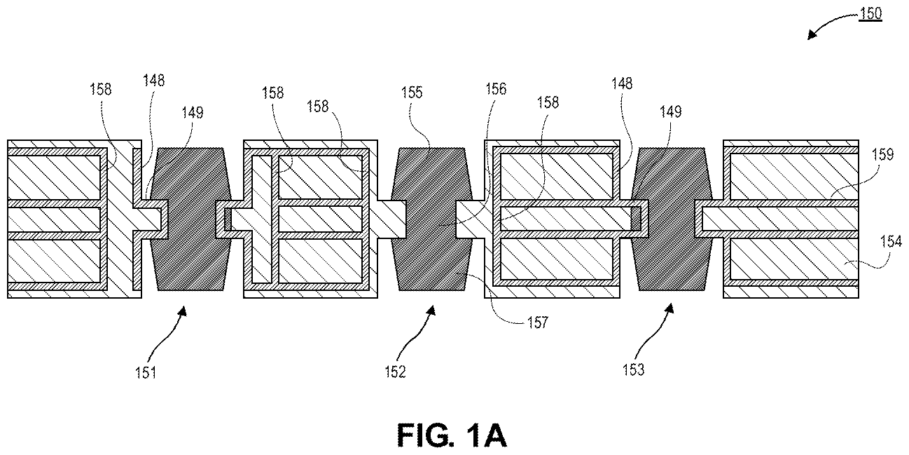

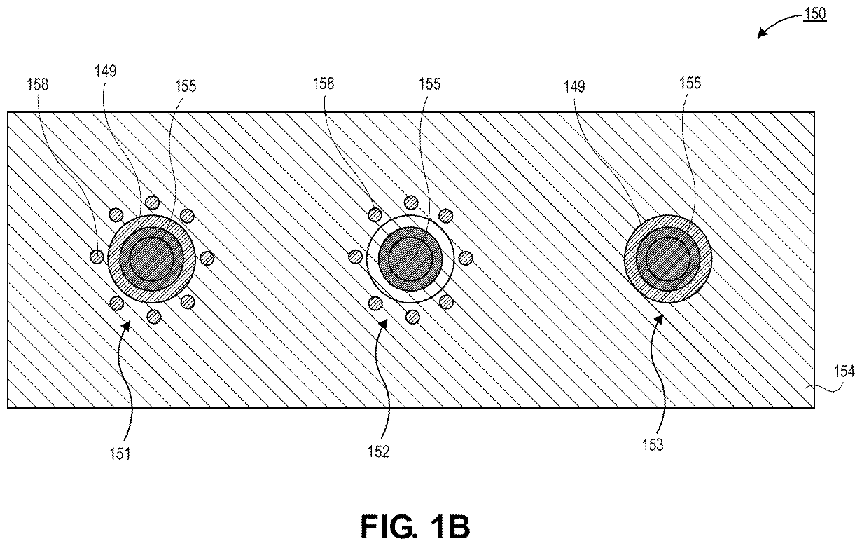

Referring now to FIG. 1A, a cross-sectional illustration of a socket 150 is shown, in accordance with an embodiment. In an embodiment, the socket 150 may comprise a socket substrate 154. The socket substrate 154 may be an organic substrate. For example, the socket substrate 154 may be formed with similar materials used to form printed circuit boards (PCBs) or the like. In an embodiment one or more conductive planes or traces 159 may be provided in the socket substrate 154. The planes or traces 159 may be ground planes or power planes in some embodiments.

As shown in FIG. 1A, a set of three pins 151-153 is shown as an example. It is to be appreciated that more than three pins 151-153 may be included in the socket 150, but are not shown for simplicity. In an embodiment, a first pin 151 may be a power pin, the second pin 152 may be a signal pin, and the third pin 153 may be a ground pin. Each of the pins 151-153 may comprise a first head 155, a middle portion 156, and a second head 157. The middle portion 156 may be narrower than the first head 155 and the second head 157. In an embodiment, the middle portion 156 may be directly contacting the socket substrate 154. For example, the signal pin 152 has portions that directly contact the socket substrate 154. In other embodiments, the middle portion 156 may be spaced away from the socket substrate 154 by a conductive layers 148/149 that line the opening through the socket substrate 154. For example, conductive layers 148 and 149 may be provided on the ground pin 153 and the power pin 151. In an embodiment, the sidewalls of the first head 155 and the second head 157 may be spaced apart from the sidewalls of the openings through the socket substrate 154. Additionally, the conductive layers 148 may also be spaced away from the first head 155 and the second head 157 in the ground pin 153 and the power pin 151.

In an embodiment, the pins 151-153 may comprise an elastomeric material. For example, the elastomeric material may be an electrically conductive material. In some embodiments, conductive particles (e.g., metal particles) may be included in an elastomeric matrix. As such, the conductive particles provide a conductive path through the elastomeric matrix in order to conduct electricity. While referred to sometimes as elastomeric pins herein, it is to be appreciated that other conductive materials may be used for the pins 151-153 in some embodiments. For example, the pins 151-153 may be any standard pin material, such as copper pins or the like.

In an embodiment, the height of the pins 151-153 may be smaller than a thickness of the socket substrate 154. That is, a top surface of the first head 155 may be below (in the Z-direction) a top surface of the socket substrate 154, and/or a bottom surface of the second head 157 may be above (in the Z-direction) a bottom surface of the socket substrate 154. As will be appreciated, this allows for the entire length of the pins 151-153 to be shielded. For example, the shielding may be provided by one or more vias 158 that surround the pins 151 and 152. Pin 153 may not be surrounded by vias 158. Instead, the pin 153 may be shorted to a ground plane 159 by conductive layers 148 and/or 149. In some embodiments, the vias 158 may be electrically coupled to ground planes 159.

Referring now to FIG. 1B, a plan view illustration of the socket 150 is shown, in accordance with an embodiment. As shown, the socket 150 may comprise a first pin 151 that is a power pin, a second pin 152 that is a signal pin, and a third pin 153 that is a ground pin. In an embodiment, the first pin 151 may comprise a first head 155 that is within an opening in the socket substrate 154. The opening may be lined with a metal layer 149. In an embodiment, a plurality of vias 158 may surround the perimeter of the first head 155. The vias 158 may have diameters that are smaller than the diameter of the opening in which the first head 155 is located. The vias 158 may extend through a thickness of the socket substrate 154. In an embodiment, eight vias 158 are provided around the first head 155. However, it is to be appreciated that any number of vias 158 may be used.

In an embodiment, the second pin 152 is a signal pin. The first head 155 may be provided in an opening in the socket substrate 154. As shown, there may not be a conductive plating surrounding the first head 155 of the second pin 152. In an embodiment, a plurality of vias 158 may surround a perimeter of the first head 155 of the second pin 152. The diameters of the vias 158 may be smaller than a diameter of the opening into the socket substrate 154 in which the second pin 152 is formed. The vias 158 may pass through a thickness of the socket substrate 154. In an embodiment, eight vias 158 are provided around the first head 155. However, it is to be appreciated that any number of vias 158 may be used for the second pin 152.

In an embodiment, the third pin 153 is a ground pin. The third pin 153 may include a first head 155 that is within an opening in the socket substrate 154. The opening may be lined with a conductive layer 149. In an embodiment, there are no vias surrounding the third pin 153. However, in some embodiments, vias may be included around the third pin 153.

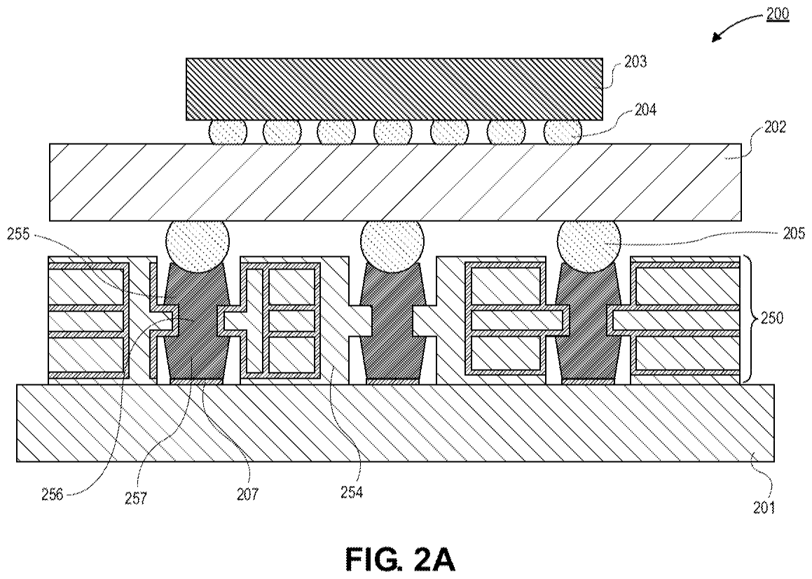

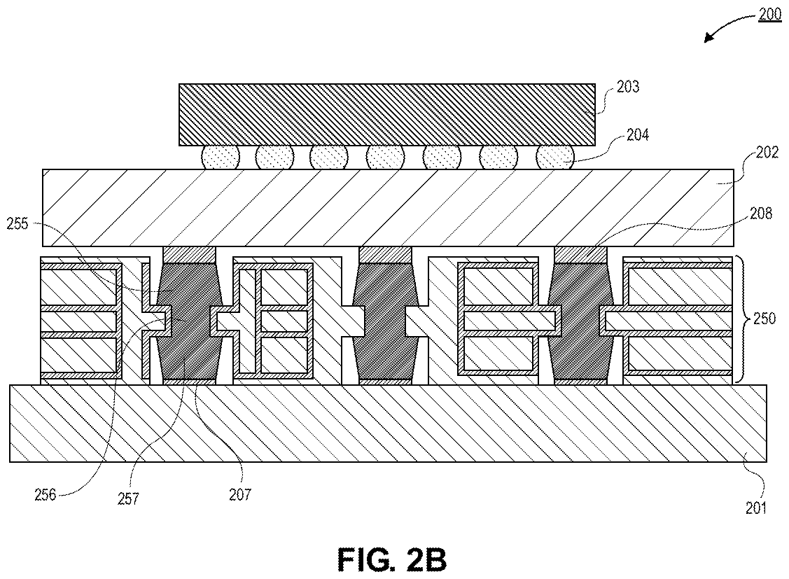

Referring now to FIG. 2A, a cross-sectional illustration of an electronic system 200 is shown, in accordance with an embodiment. In an embodiment, the electronic system 200 comprises a die 203. The die 203 may be any type of semiconductor device. For example, the die 203 may be a processor, a graphics processor, an SoC, a memory die, or the like. Additionally, while a single die 203 is shown, it is to be appreciated that the electronic system 200 may comprise a plurality of dies 203. For example, the dies 203 may be stacked over each other or adjacent to each other. In the case of adjacent dies 203, the dies 203 may be coupled together by a bridge die or the like.

In an embodiment, the die 203 may be coupled to a package substrate 202. For example first level interconnects (FLIs) 204 may couple the die 203 to the package substrate 202. The FLIs 204 may be solder bumps, or any other FLI architecture. In an embodiment, the package substrate 202 may be any suitable packaging substrate. For example, the package substrate 202 may comprise an organic substrate. The organic substrate may include a plurality of laminated layers. Conductive routing (not shown) may be provided in the laminated layers. For example, pads, traces, vias, and the like may be provided in the package substrate 202. The conductive routing may electrically couple FLIs 204 to second level interconnects (SLIs) 205. The package substrate 202 may be a coreless substrate. In other embodiments, the package substrate 202 may comprise a core (not shown).

In the illustrated embodiment, the die 203 is directly coupled to the package substrate 202. However, it is to be appreciated that an interposer or the like (not shown) may be provided between the die 203 and the package substrate 202. An interposer may include an inorganic substrate. In some embodiments, the interposer may be a silicon interposer. In other embodiments, the interposer may be a glass interposer. Conductive routing through the interposer may couple the die 203 to the underlying package substrate 202.

In an embodiment, the SLIs 205 may be solder balls. For example, the SLIs 205 may be ball grid array (BGA) balls or the like. The SLIs 205 may be coupled to the socket 250. Particularly, the SLIs 205 may contact the top head 255 of a pin through the socket substrate 254. In an embodiment, the pin may comprise the top head 255, a bottom head 257, and a middle region 256 between the top head 255 and the bottom head 257. The pin may be an elastomeric pin. In order to conduct electricity between the SLIs 205 and the underlying board 201, the elastomeric pin may be a conductive elastomeric material. While shown as an elastomeric pin, it is to be appreciated that other compliant pin architectures may be used to replace the top head 255, the bottom head 257, and the middle region 256. For example, pogo-pins or spring probe pins may also be used in some embodiments.

The socket 250 may be substantially similar to any of the sockets described in greater detail above. For example, the pins may include ground pins (right), signal pins (center), and power pins (left). In an embodiment, the pins may have bottom heads 257 that are coupled to pads 207. The pads 207 may be provided on the underlying board 201. The board 201 may be a printed circuit board (PCB) or the like. In an embodiment, the pads 207 may be substantially below an overlying SLI 205. However, as will be described in greater detail below, the pads 207 may be offset from the overlying SLIs 205.

In an embodiment, the SLIs 205 may be partially shielded. That is, the SLIs 205 may extend into the opening through the socket substrate 254. The vias surrounding the pins may also partially surround the SLIs 205. As such, improved shielding and a reduction in cross-talk may be provided in some embodiments. Particularly, increasing the amount of the SLIs 205 that are shielded may provide improved resistance to unwanted cross-talk.

Referring now to FIG. 2B, a cross-sectional illustration of an electronic system 200 is shown, in accordance with an additional embodiment. In an embodiment, the electronic system 200 in FIG. 2B may be substantially similar to the electronic system 200 in FIG. 2A, with the exception of the architecture of the SLIs. Instead of being BGA balls, the SLIs 208 may be pads. For example, the pads 208 may be suitable for a land grid array (LGA) architecture. That is, instead of coupling a solder ball to pad 207, the elastomeric pin couples an SLI pad 208 to the pad 207 on the board 201.

In FIGS. 1A-2B, the sockets are described as having pins that extend through the thickness of the socket substrate. However, it is to be appreciated that in other embodiments, the pins may be split into a top portion and a bottom portion. An electrical coupling between the top portion and the bottom portion connects the top surface socket to the bottom surface of the socket. In some embodiments, the electrical coupling is made directly by a conductive feature (e.g., a trace and/or via). In other embodiments, the electrical coupling is a capacitive coupling between pads connected to the top head of the pin and the bottom head of the pin.

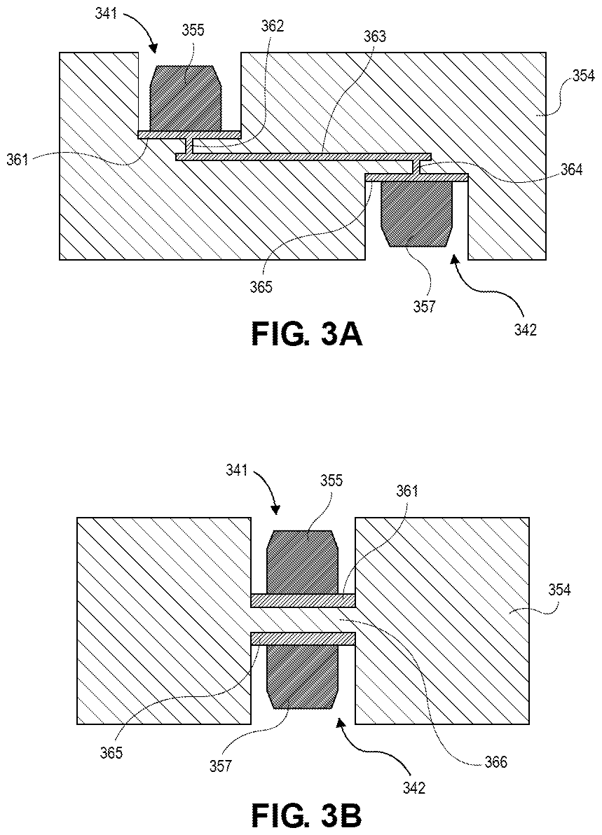

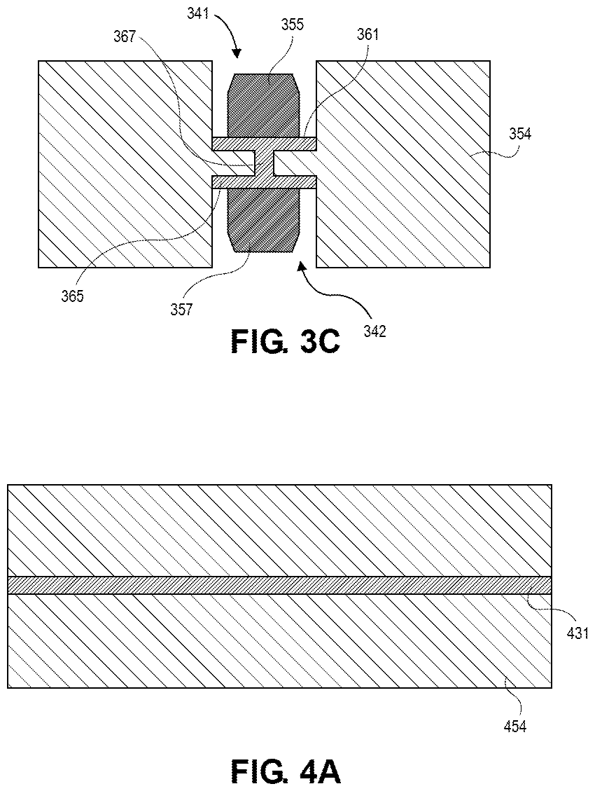

Referring now to FIG. 3A, a cross-sectional illustration of a pin in a socket substrate 354 is shown, in accordance with an embodiment. In an embodiment, the socket substrate 354 includes a pair of blind recesses 341 and 342. As used herein, a blind recess refers to a cavity into a surface of a substrate that does not pass entirely through a thickness of the substrate. For example, blind recess 341 extends into the top surface of the socket substrate 354, but does not extend to the bottom surface of the socket substrate 354. Similarly, blind recess 342 extends into the bottom surface of the socket substrate 354, but does not extend to the top surface of the socket substrate 354.

In an embodiment, the blind recess 341 may be laterally offset from the blind recess 342. The offset nature of the blind recesses 341 and 342 allow for a horizontal displacement pin structure. For example, the top head 355 of the pin may occupy a first location in the X-Y plane, and the bottom head 357 may occupy a second location in the X-Y plane that is different than the first location. As such, signals can be horizontally routed to accommodate differences in the location of pads between a package substrate and a board.

In an embodiment, the horizontal routing is enabled by the use of embedded traces 363 and vias 362 and 364. For example, top head 355 may be attached to a first pad 361. The first pad 361 may be electrically coupled to trace 363 by the via 362. In an embodiment, the trace 363 may be coupled to a second via 364 that is electrically coupled to a second pad 365. The bottom head 357 may be coupled to the second pad 365. Accordingly, a direct electrical connection is provided between the top head 355 and the bottom head 357.

Referring now to FIG. 3B, a cross-sectional illustration of a pin in a socket substrate 354 is shown, in accordance with an additional embodiment. Instead of making a direct electrical connection, the first pad 361 is capacitively coupled to the second pad 365. For example, the first opening 341 may be directly above the second opening 342. A region 366 of the socket substrate 354 may separate the bottoms of the openings 341 and 342. As such, an electrode-dielectric-electrode structure is provided between the top head 355 and the bottom head 357.

Referring now to FIG. 3C, a cross-sectional illustration of a pin in a socket substrate 354 is shown, in accordance with an additional embodiment. The pin may have a structure similar to the structure shown in FIG. 3B, with the addition of a direct electrical coupling between the first pad 361 and the second pad 365. For example, a via 367 may couple the first pad 361 to the second pad 365.

In FIGS. 3A-3C, illustrations of the pin are shown in isolation from other components. For example, one or more conductive vias may be formed around the pins in order to provide electrical isolation. In such embodiments, the vias may be formed with a mechanical drilling process or the like. Diameters of the vias may be less than the diameters of the first opening 341 and the second opening 342. In an embodiment, the interior surfaces of the first opening 341 and the second opening 342 may also be plated, similar to embodiments described in greater detail above.

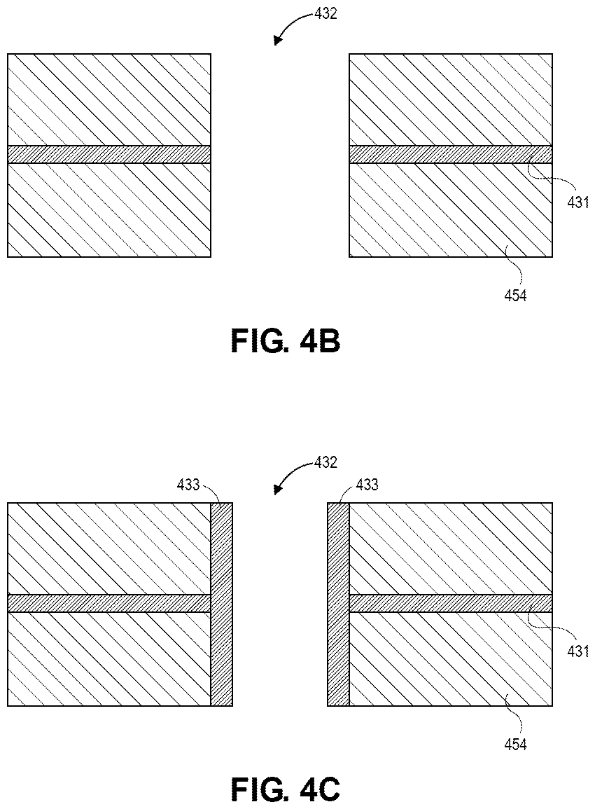

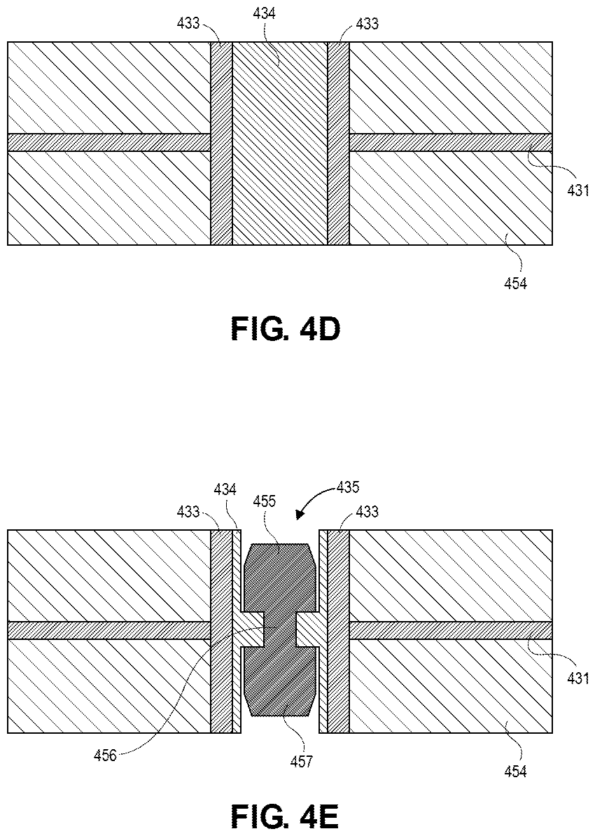

Referring now to FIGS. 4A-4E, a series of cross-sectional illustrations depicting a process that may be used to form pins in a socket substrate 454 is shown, in accordance with an embodiment. In the illustrated embodiment, the pin is surrounded by a conductive shield that surrounds the elastomeric pin. The conductive shield is fabricated with a plating process after an initial drill through the socket substrate 454. A fill material is then deposited in the remaining portion of the opening, and a second opening is drilled through the fill material. The elastomeric pin may then be inserted into the second opening.

Referring now to FIG. 4A, a cross-sectional illustration of a socket substrate 454 is shown, in accordance with an embodiment. In an embodiment, one or more conductive planes and/or traces 431 may be provided in the socket substrate 454. For example, a single trace 431 is shown in FIG. 4A, but it is to be appreciated that two or more planes and/or traces 431 may be included in the socket substrate 454, similar to embodiments shown above.

In an embodiment, the socket substrate 454 may be an organic substrate material. For example, the socket substrate 454 may comprise a glass fiber reinforced dielectric material typical of PCB substrates. In an embodiment, the conductive planes and/or traces 431 may be copper or the like. In other embodiments, the socket substrate 454 may include materials typical of package substrates, such as buildup films or the like.

Referring now to FIG. 4B, a cross-sectional illustration of the socket substrate 454 is shown after a first opening 432 is formed through a thickness of the socket substrate 454. In an embodiment, the first opening 432 may be formed with a mechanical drilling process. However, it is to be appreciated that other drilling processes (e.g., laser drilling, etc.) may be used to form the first opening 432. In other embodiments, an etching process may be used to form the first openings 432. In the illustrated embodiment, the sidewalls of the first opening 432 are substantially vertical. Depending on the drilling method used, sidewalls of the first opening 432 may be tapered, hourglass shaped, or the like.

Referring now to FIG. 4C, a cross-sectional illustration of the socket substrate 454 after a plating process is shown, in accordance with an embodiment. As shown, the plating process may result in a conductive shell 433 being provided on the sidewalls of the first opening 432. Excess metal on the top and bottom surfaces of the socket substrate 454 may be removed with a polishing process, or the metal may be prevented from depositing on the top and bottom surfaces (e.g., using masking or the like). In an embodiment, the conductive shell 433 will provide electrical shielding to the subsequently formed pin. In some embodiments, the conductive shell 433 may be electrically coupled to the trace/plane 431. For example, the trace/plane 431 may be a ground trace/plane that allows for the conductive shell 433 to be grounded as well.

Referring now to FIG. 4D, a cross-sectional illustration of the socket substrate 454 after a fill layer 434 is deposited into the first opening 432 is shown, in accordance with an embodiment. In an embodiment, the fill layer 434 may entirely fill the remainder of the first opening 432. In an embodiment, excess material may be removed from the top and bottom surfaces of the socket substrate 454 using an etching and/or a polishing or grinding process. In an embodiment, the fill layer 434 may be an insulating material. For example, the fill layer 434 may be an epoxy or the like.

Referring now to FIG. 4E, a cross-sectional illustration of the socket substrate after a second opening 435 is formed in the fill layer 434 and a pin is inserted into the second opening 435 is shown, in accordance with an embodiment. In an embodiment, the second opening 435 may be formed with a drilling process. For example, a mechanical drilling process may be used to form the second opening 435. In an embodiment, the second opening 435 may have a stepped profile. For example, a top portion and a bottom portion of the second opening 435 have a first width, and a middle portion between the top portion and the bottom portion may have a second width that is smaller than the first width. Such a structure may be formed by drilling a first hole through the thickness of the fill layer 434 that has the second width. Blind second holes with the first width may then be drilled on each side of the fill layer 434. In other embodiments, a width of the second opening 435 may be substantially uniform through its thickness.

As shown, a pin is inserted into the second opening 435. In some embodiments, the pin is a conductive elastomeric pin. The pin may comprise a top head 455, a middle portion 456, and a bottom head 457. Though, in embodiments with a uniform second opening 435 width, there may be no width variations that clearly define the top head 455, the middle portion 456, and the bottom head 457. While described herein as being an elastomeric pin, it is to be appreciated that other materials (e.g., copper or other conductive solids) may be used instead of an elastomeric pin. As shown, the middle portion 456 may be in direct contact with the fill layer 434, and the top head 455 and the bottom head 457 may be spaced away from the fill layer 434. In other embodiments, the bottom head 457 and the top head 455 may contact the fill layer 434.

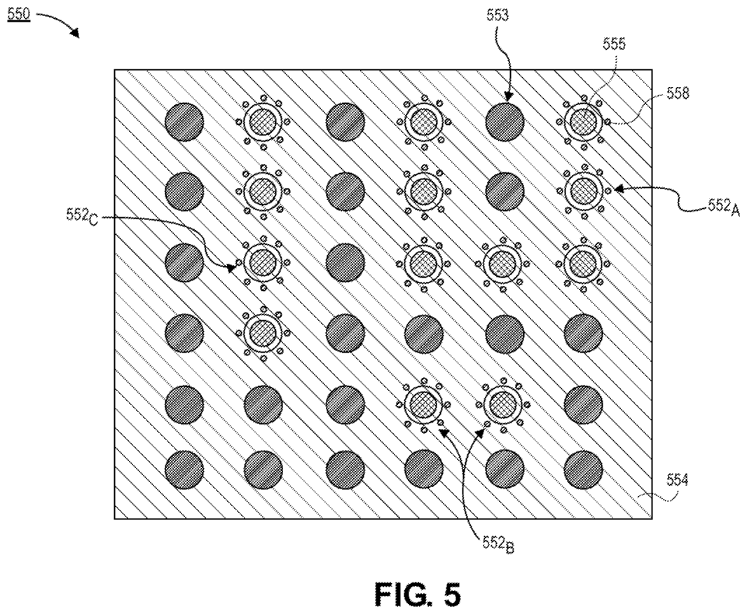

Referring now to FIG. 5, a plan view illustration of a socket 550 is shown, in accordance with an embodiment. As shown, a plurality of signal pins 552_{A-C} may be included in the socket substrate 554. The signal pins 552_{A-C} may be surrounded by ground pins 553. The signal pins may be provided in various layouts. However, due to the vias 558 that surround the top heads 555, the signal pins are electrically isolated from each other. In an embodiment, the signal pins 552_{A} may be in a u-shaped layout. The signal pins 552_{B} may be differential signaling pairs, and the signal pins 552_{C} may be provided in a linear arrangement. While three different patterns are shown in FIG. 5, it is to be appreciated that the signal pins 552 may be provided in any suitable layout.

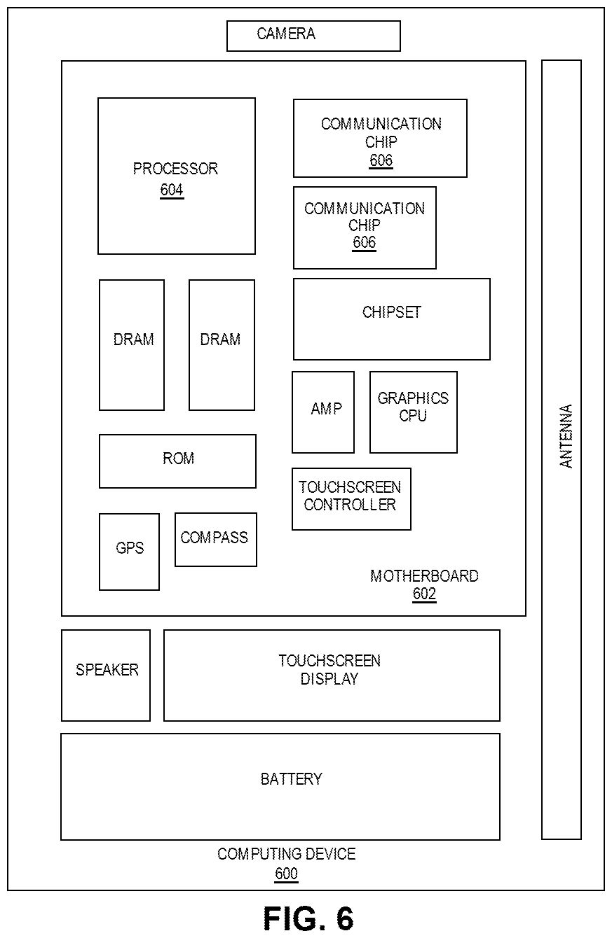

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be tested with a socket that includes elastomeric pins that are surrounded by grounded vias or a grounded shell, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be tested with a socket that includes elastomeric pins that are surrounded by grounded vias or a grounded shell, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a socket, comprising: a substrate; an opening through the substrate; and an elastomeric pin inserted into the opening, wherein the elastomeric pin is electrically conductive.

Example 2: the socket of Example 1, wherein the opening comprises a first blind recess into a first surface of the substrate, and a second blind recess into a second surface of the substrate.

Example 3: the socket of Example 2, wherein the first blind recess is coupled to the second blind recess by a hole through the substrate.

Example 4: the socket of Example 3, wherein the elastomeric pin has a first head that is positioned in the first blind recess and a second head that is positioned in the second blind recess.

Example 5: the socket of Example 4, wherein a diameter of the first head and a diameter of the second head are greater than a diameter of the hole through the substrate.

Example 6: the socket of Examples 1-5, wherein a plurality of vias through the substrate surround a perimeter of the elastomeric pin.

Example 7: the socket of Example 6, wherein diameters of the plurality of vias are smaller than a diameter of the elastomeric pin.

Example 8: the socket of Examples 1-7, wherein interior surfaces of the opening are plated.

Example 9: the socket of Example 8, wherein the plated interior surfaces are shorted to a grounded feature.

Example 10: the socket of Examples 1-9, wherein a top of the elastomeric pin is below a top surface of the substrate.

Example 11: the socket of Examples 1-10, wherein the elastomeric pin is coupled to a package substrate.

Example 12: the socket of Example 11, wherein the package substrate is coupled to the elastomeric pin by a solder ball.

Example 13: the socket of Example 11, wherein the package substrate is coupled to the elastomeric pin by a land grid array (LGA) pad.

Example 14: a socket, comprising: a substrate with a first surface and a second surface opposite from the first surface; a first blind recess into the first surface of the substrate; a second blind recess into the second surface of the substrate; a first elastomeric pin inserted into the first blind recess; and a second elastomeric pin inserted into the second blind recess, wherein the first and second elastomeric pins are electrically conductive.

Example 15: the socket of Example 14, wherein a first pad is below the first elastomeric pin and a second pad is above the second elastomeric pin.

Example 16: the socket of Example 15, wherein the first pad and the second pad form a capacitor.

Example 17: the socket of Example 15, wherein the first pad is coupled to the second pad by a via.

Example 18: the socket of Examples 14-17, wherein the first blind recess is offset from the second blind recess.

Example 19: the socket of Example 18, wherein the first elastomeric pin and the second elastomeric pin are coupled to each other by a via and a trace.

Example 20: an electronic system, comprising: a die; a package substrate coupled to the die; a socket coupled to the package substrate, wherein the socket comprises: compliant pins that pass through a thickness of a socket substrate; and a board coupled to the socket.

Example 21: the electronic system of Example 20, wherein the compliant pins are elastomeric pins.

Example 22: the electronic system of Example 21, wherein the elastomeric pins are positioned in openings through the socket substrate, wherein the openings have a first end, a second end, and a middle between the first end and the second end, and wherein the middle is narrower than the first end and the second end.

Example 23: the electronic system of Example 21 or Example 22, wherein the elastomeric pins are surrounded by conductive vias.

Example 24: the electronic system of Examples 21-22, wherein the elastomeric pins are coupled to the package substrate by solder balls.

Example 25: the electronic system of Example 20, wherein the compliant pins are spring probes or pogo-pins.

What is claimed is:

1. A socket, comprising:
a substrate;
an opening through the substrate; and
an elastomeric pin inserted into the opening, wherein the elastomeric pin is electrically conductive.

2. The socket of claim 1, wherein the opening comprises a first blind recess into a first surface of the substrate, and a second blind recess into a second surface of the substrate.

3. The socket of claim 2, wherein the first blind recess is coupled to the second blind recess by a hole through the substrate.

4. The socket of claim 3, wherein the elastomeric pin has a first head that is positioned in the first blind recess and a second head that is positioned in the second blind recess.

5. The socket of claim 4, wherein a diameter of the first head and a diameter of the second head are greater than a diameter of the hole through the substrate.

6. The socket of claim 1, wherein a plurality of vias through the substrate surround a perimeter of the elastomeric pin.

7. The socket of claim 6, wherein diameters of the plurality of vias are smaller than a diameter of the elastomeric pin.

8. The socket of claim 1, wherein interior surfaces of the opening are plated.

9. The socket of claim 8, wherein the plated interior surfaces are shorted to a grounded feature.

10. The socket of claim 1, wherein a top of the elastomeric pin is below a top surface of the substrate.

11. The socket of claim 1, wherein the elastomeric pin is coupled to a package substrate.

12. The socket of claim 11, wherein the package substrate is coupled to the elastomeric pin by a solder ball.

13. The socket of claim 11, wherein the package substrate is coupled to the elastomeric pin by a land grid array (LGA) pad.

14. A socket, comprising:
a substrate with a first surface and a second surface opposite from the first surface;
a first blind recess into the first surface of the substrate;
a second blind recess into the second surface of the substrate;
a first elastomeric pin inserted into the first blind recess; and
a second elastomeric pin inserted into the second blind recess, wherein the first and second elastomeric pins are electrically conductive.

15. The socket of claim 14, wherein a first pad is below the first elastomeric pin and a second pad is above the second elastomeric pin.

16. The socket of claim 15, wherein the first pad and the second pad form a capacitor.

17. The socket of claim 15, wherein the first pad is coupled to the second pad by a via.

18. The socket of claim 14, wherein the first blind recess is offset from the second blind recess.

19. The socket of claim 18, wherein the first elastomeric pin and the second elastomeric pin are coupled to each other by a via and a trace.

20. An electronic system, comprising:
a die;
a package substrate coupled to the die;
a socket coupled to the package substrate, wherein the socket comprises:
compliant pins that pass through a thickness of a socket substrate; and
a board coupled to the socket.

21. The electronic system of claim 20, wherein the compliant pins are elastomeric pins.

22. The electronic system of claim 21, wherein the elastomeric pins are positioned in openings through the socket substrate, wherein the openings have a first end, a second end, and a middle between the first end and the second end, and wherein the middle is narrower than the first end and the second end.

23. The electronic system of claim 21, wherein the elastomeric pins are surrounded by conductive vias.

24. The electronic system of claim 21, wherein the elastomeric pins are coupled to the package substrate by solder balls.

25. The electronic system of claim 20, wherein the compliant pins are spring probes or pogo-pins.
